(19) United States
(12) Patent Application Publication
(10) Pub. No.: US 2018/0114048 A1
(43) Pub. Date: Apr. 26, 2018

(54) CHIP PACKAGING METHOD AND CHIP PACKAGING STRUCTURE

(71) Applicant: China Wafer Level CSP Co., Ltd., Suzhou, Jiangsu (CN)

(72) Inventors: Zhiqi Wang, Suzhou, Jiangsu Province (CN); Ying Yang, Suzhou, Jiangsu Province (CN); Qiong Yu, Suzhou, Jiangsu Province (CN); Wei Wang, Suzhou, Jiangsu Province (CN)

(73) Assignee: China Wafer Level CSP Co., Ltd., Suzhou, Jiangsu (CN)

(21) Appl. No.: 15/572,455

(22) PCT Filed: Sep. 16, 2015
(86) PCT No.: PCT/CN2015/089701

§ 371 Date: Nov. 7, 2017

(30) Foreign Application Priority Data
May 19, 2015 (CN) 201510256311.9

(51) Int. Cl. G06K 9/00; H01L 23/31; H01L 23/29; H01L 23/64

(52) U.S. Cl. CPC G06K 9/00006; H01L 23/3114; H01L 23/642; H01L 23/293; H01L 23/291; H01L 23/3142

(57) ABSTRACT

A chip packaging method and a chip packaging structure are provided. The packaging structure includes: a substrate; a sensing chip coupled to the substrate, the sensing chip including a first surface, a second surface, and a sensing area at the first surface, the second surface facing the substrate; a cover plate on the sensing area, the cover plate-having a third surface-in contact with the sensing area, and a fourth surface; and a plastic package layer on the substrate, the plastic package layer surrounding the sensing chip and covering part of the sidewall of the cover plate, the surface of the plastic package layer being higher than the third surface and lower than the fourth surface.

### CROSS REFERENCE OF RELATED APPLICATION

The present disclosure claims the priority to Chinese Patent Application No. 201510256311.9, titled “CHIP PACKAGING METHOD AND CHIP PACKAGING STRUCTURE”, filed on May 19, 2015 with the State Intellectual Property Office of People's Republic of China, the content of which is incorporated herein by reference in its entirety.

### TECHNICAL FIELD

The present disclosure relates to the technical field of semiconductor manufacture, in particular, to a chip packaging method and a chip packaging structure.

### BACKGROUND

With development of modern society, importance of personal identification and personal information security gradually draws people's attention. Due to uniqueness and invariability of human fingerprint, fingerprint recognition technology has features of high security, high reliability and simple and convenient usage, so that the fingerprint recognition technology is widely applied to various fields of personal information security protection. With continuing development of science and technology, information security problem of various electronic products is always a key point in technology development. Particularly, for mobile terminals, such as mobile phones, notebook computers, tablet computers and digital cameras, requirement for information security is more prominent.

Sensing manner of fingerprint recognition device includes capacitive manner (electric field manner) and inductive manner. The fingerprint recognition device acquires fingerprint information of a user by extracting the user's fingerprint and converting the user's fingerprint into an electrical signal. Specifically, shown in FIG. 1 is a schematic structural diagram of a section of a fingerprint recognition device, including: a substrate 100, a fingerprint recognition chip 101 coupled to a surface of the substrate 100, and a glass substrate 102 covering a surface of the fingerprint recognition chip 101.

Taking a capacitive fingerprint recognition chip as an example, the fingerprint recognition chip 101 includes one or more capacitance plates. Because there are convex ridges and concave valleys on epidermis or subcutaneous layer of a user's finger, when the user's finger 103 touches a surface of the glass substrate 102, the distance from the ridges to the fingerprint recognition chip 101 is different from the distance from the valleys to the fingerprint recognition chip 101. Therefore, capacitance value between the ridges and the capacitance plate is different from capacitance value between the valleys and the capacitance plate, and the fingerprint recognition chip 101 can acquire the different capacitance values and converts the capacitance values into corresponding electrical signals to output the electrical signals. After the fingerprint recognition device collects the received electrical signals, it can acquire the fingerprint information of the user.

However, in conventional fingerprint recognition devices, the high requirement for sensitivity of the fingerprint recognition chips limits manufacture and application of the fingerprint recognition devices.

### SUMMARY

A chip packaging method and a chip packaging structure are provided according to embodiments of the present disclosure. The packaging structure can enhance a binding force between a cover plate and a sensing chip, increasing reliability of the packaging structure.

A chip packaging method is provided according to some embodiments of the present disclosure, including:

providing a substrate;

coupling a sensing chip with the substrate, where the sensing chip includes a first surface and a second surface opposite to the first surface, and the sensing chip further includes a sensing region at the first surface, and the second surface of the sensing chip faces the substrate;

forming a cover plate on the sensing region of the sensing chip, where the cover plate includes a third surface contacting the sensing region and a fourth surface opposite to the third surface; and

forming a plastic packaging layer on the substrate, where the plastic packaging layer surrounds the sensing chip and covers a part of a sidewall of the cover plate, and a surface of the plastic packaging layer is higher than the third surface of the cover plate and lower than the fourth surface of the cover plate.

Optionally, formation technique of the plastic packaging layer is fluid plastic package technique.

Optionally, formation technique of the plastic packaging layer includes potting technique.

Optionally, the plastic packaging layer includes polymer materials.

Optionally, further included are: the sensing chip further includes a peripheral region at the first surface which surrounds the sensing region, the peripheral region and the sensing region of the sensing chip includes a chip circuit, a first pad is located at a surface of the peripheral region of the sensing chip, and the chip circuit is connected to the first pad.

Optionally, further included is that the substrate includes a fifth surface, where the sensing chip is coupled to the fifth surface of the substrate, and the fifth surface of the substrate includes a second pad.

Optionally, further included is forming a conductive wire before forming the plastic packaging layer, where two ends of the conductive wire are connected to the first pad and the second pad respectively.

Optionally, the conductive wire has a point with a maximum distance to the surface of the substrate, where the point of the conductive wire with the maximum distance to the surface of the substrate is a vertex, and the surface of the plastic packaging layer is higher than the vertex and lower than the surface of the cover plate.

Optionally, further included are: forming a first adhesive layer at the surface of the substrate or the second surface of the sensing chip, before coupling the sensing chip with the substrate; and fixing the sensing chip to the substrate through the first adhesive layer.

Optionally, further included are: forming a second adhesive layer on the first surface of the sensing chip; and forming the cover plate on the second adhesive layer.

A chip packaging structure is further provided according to some embodiments of the present disclosure, including:

a substrate;

a sensing chip coupled with the substrate, where the sensing chip includes a first surface and a second surface opposite to the first surface, and the sensing chip further includes a sensing region at the first surface, and the second surface of the sensing chip faces the substrate;

a cover plate on the sensing region of the sensing chip, where the cover plate includes a third surface contacting the sensing region, and a fourth surface opposite to the third surface; and

a plastic packaging layer on the substrate, where the plastic packaging layer surrounds the sensing chip and covers a part of a sidewall of the cover plate, and a surface of the plastic packaging layer is higher than the third surface of the cover plate and lower than the fourth surface of the cover plate. Optionally, the plastic packaging layer comprises polymer materials.

Optionally, further included are: the sensing chip further includes a peripheral region at the first surface which surrounds the sensing region, the peripheral region and the sensing region of the sensing chip includes a chip circuit, a first pad is located at a surface of the peripheral region of the sensing chip, and the chip circuit is connected to the first pad.

Optionally, further included is that the substrate includes a fifth surface, where the sensing chip is coupled to the fifth surface of the substrate, and the fifth surface of the substrate includes a second pad.

Optionally, further included is a conductive wire, where two ends of the conductive wire are connected to the first pad and the second pad respectively.

Optionally, the conductive wire has a point with a maximum distance to the surface of the substrate, where the point of the conductive wire with the maximum distance to the surface of the substrate is a vertex, and the surface of the plastic packaging layer is higher than the vertex and lower than the surface of the cover plate.

Optionally, further included is a first adhesive layer on the surface of the substrate or the second surface of the sensing chip, where the sensing chip is fixed to the substrate through the first adhesive layer.

Optionally, further included are a second adhesive layer on the first surface of the sensing chip and the cover plate on the surface of the second adhesive layer.

### BRIEF DESCRIPTION OF THE DRAWINGS

FIG. 1 is a schematic structural diagram of a section of a fingerprint recognition device;

FIG. 2 is a schematic structural diagram of a section of another fingerprint recognition chip structure; and

FIG. 3 to FIG. 7 are schematic structural diagrams of sections of chip packaging processes according to an embodiment of the present disclosure.

### DETAILED DESCRIPTION OF THE EMBODIMENTS

As described in the background, in conventional fingerprint recognition devices, the high requirement for sensitivity of fingerprint recognition chips limits manufacture and application of the fingerprint recognition devices.

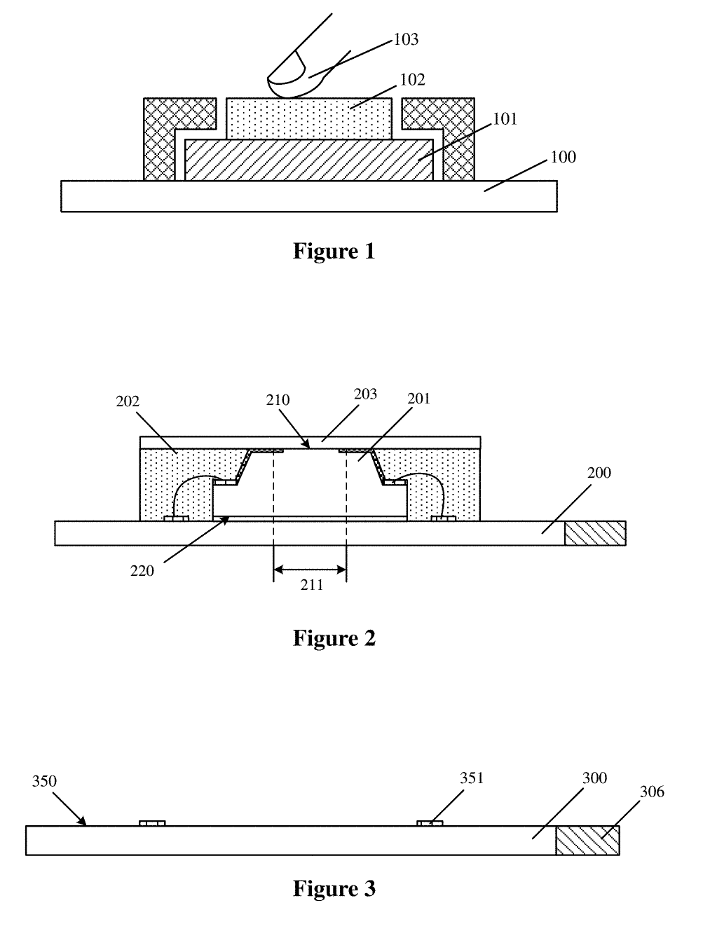

From studies it is found that, as referred to FIG. 1, a surface of the fingerprint recognition chip 101 is covered with a glass substrate 102 for protecting the fingerprint recognition chip 101, and a user's finger 103 directly contacts the glass substrate 102. Therefore, the thickness of the glass structure 102 is large to ensure that the glass structure 102 has sufficient protection ability. However, due to the large thickness of the glass structure 102, there is a high requirement for sensitivity of the fingerprint recognition chip 101 to ensure that the user's fingerprint can be extracted precisely. However, the fingerprint recognition chip with high sensitivity is difficult to manufacture and has a high manufacturing cost, thereby limiting application and promotion of the fingerprint recognition chip.

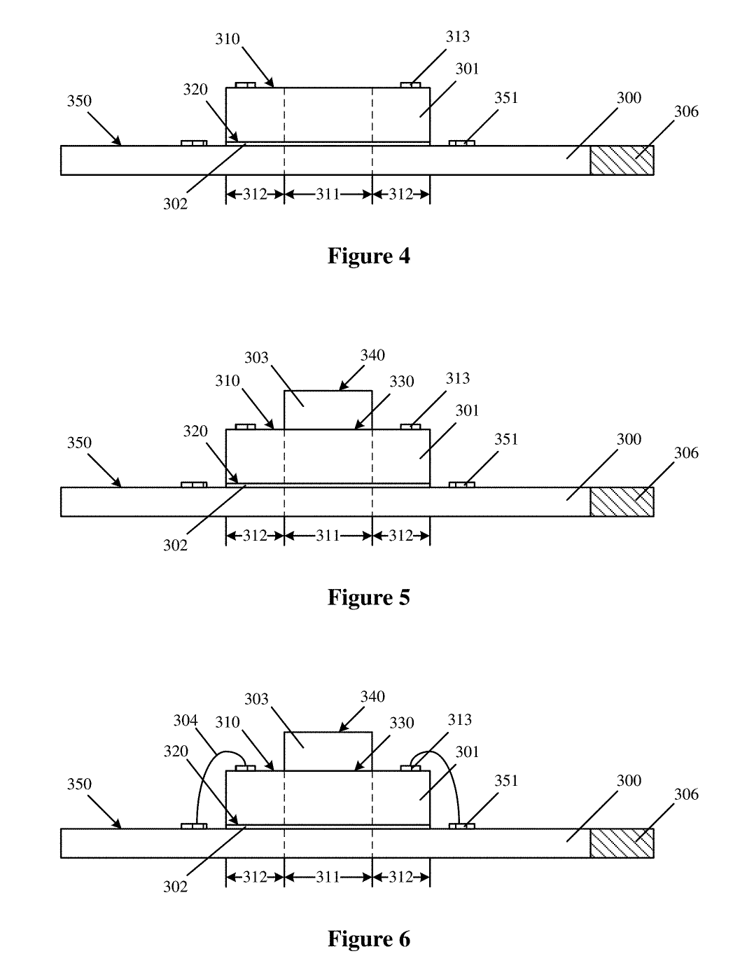

To reduce requirement for sensitivity of the fingerprint recognition chip, another fingerprint recognition chip structure is provided, as referred to FIG. 2, including: a substrate 200; a sensing chip 201 coupled to a surface of the substrate 200, where the sensing chip 201 includes a first surface 210 and a second surface 220 opposite to the first surface 210, the sensing chip 201 includes a sensing region 211 located at the first surface 210, and the second surface 220 of the sensing chip 201 faces the substrate 200; a plastic packaging layer 202 on the surface of the substrate 200, where the plastic packaging layer 202 surrounds the sensing chip 201, and a surface of the plastic packaging layer 202 and the first surface 210 of the sensing chip 201 are co-planar; a cover layer 203 on the plastic packaging layer 202 and the first surface 210 of the sensing chip 201.

Materials of the cover layer 203 are polymer materials, inorganic nano materials, or ceramic materials. And the thickness of the cover layer 203 is smaller than 100 μm.

The cover layer 203 replacing the traditional glass substrate can directly contact the user's finger to protect the sensing chip 201. Moreover, because the surface of the plastic packaging layer 202 and the first surface 210 of the sensing chip 201 are co-planar, the cover layer 203 can be directly fixed to the plastic packaging layer 202 and the first surface 210 of the sensing chip 201. Compared with the traditional glass substrate, the cover layer 203 has a smaller thickness and larger hardness, and has hardness large enough to protect the first surface 210 of the sensing chip. Moreover, the cover layer 203 can reduce the distance from the first surface 210 of the sensing chip 201 to the surface of the cover layer 203, facilitating the sensing chip 201 detecting a user's fingerprint. Correspondingly, the packaging structure decreases requirement for sensitivity of the sensing chip 201.

However, the fingerprint chip structure as shown in FIG. 2 has a strict requirement for the thickness of the cover layer 203, and the cover layer 203 needs to be bound to the plastic packaging layer 202 and the first surface 210 of the sensing chip 201 through an adhesive layer, so that a binding force between the cover layer 203 and the sensing chip 201 is week, and the cover layer 203 is likely to be delaminated or peeled off from the sensing chip 201 or the plastic packaging layer 202, resulting in a decrease in sensitivity and reliability of the fingerprint sensing chip.

To address the above issues, a chip packaging method and a chip packaging structure are provided according to embodiments of the present disclosure. In the packaging structure, a cover plate is provided on a sensing region of the sensing chip, a plastic packaging layer surrounding the sensing chip is provided on the surface of the substrate, and the plastic packaging layer covers a part of the sidewall of the cover plate. The cover plate can directly contact the user's finger to protect the sensing chip. Moreover, compared with the traditional glass substrate, the cover plate can be made of materials with a smaller thickness to reduce the distance from the first surface of the sensing chip to the surface of the cover plate, facilitating the sensing chip to detect the user's fingerprint. Correspondingly, the packaging structure reduces requirement for sensitivity of the sensing chip, so that the packaging structure of the fingerprint recognition chip has a wider application. The cover plate includes a third surface contacting the sensing region and a fourth surface opposite to the third surface. The surface of the plastic packaging layer is higher than the third surface of the cover plate and lower than the fourth surface of the cover plate. Therefore, the plastic packaging layer can fix the cover plate to the first surface of the sensing chip, so that the cover plate and the sensing chip are bound together more tightly, preventing the cover plate from being delaminated or peeled off from the sensing chip, and increasing reliability of the packaging structure. And the plastic packaging layer exposes the surface of the cover plate, therefore, the plastic packaging layer does not hamper sensing performances of the sensing region of the sensing chip, and the sensing region of the sensing chip has high sensing recognition ability.

For better understanding and clearance of the above objectives, characteristics and merits of the present disclosure, hereinafter specific embodiments of the present disclosure is illustrated in details in conjunction with drawings.

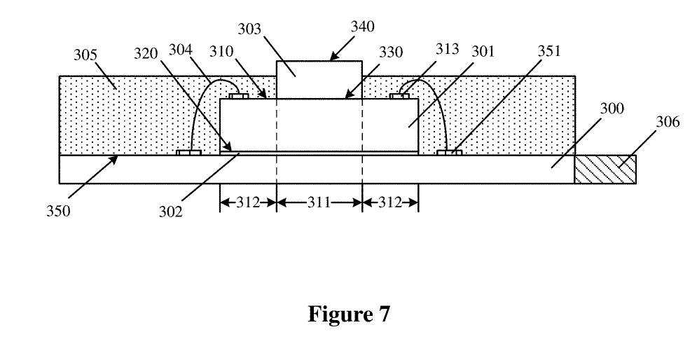

FIG. 3 to FIG. 7 are schematic structural diagrams of sections of chip packaging processes according to an embodiment of the present disclosure.

Reference is made to FIG. 3, where a substrate 300 is provided.

The substrate 300 is a hard substrate or a soft substrate. In the embodiment, the substrate 300 is the hard substrate. The hard substrate may be a PCB substrate, a glass substrate, a metal substrate, a semiconductor substrate, or a polymer substrate.

In the embodiment, the substrate 300 includes a fifth surface 350, and the fifth surface 350 of the substrate 300 may be coupled with a sensing chip. The fifth surface 350 of the substrate 300 includes a wiring layer (not shown) and second pads 351, where the wiring layer is connected to the second pads 351, and the second pads 351 may be connected to a chip circuit at a surface of a sensing chip.

In the embodiment, a connecting piece 306 is formed at an end of the substrate 300. The connecting piece 306 may connect the sensing chip to an external circuit. Materials of the connecting piece 306 includes conductive materials, and the connecting piece 306 is electrically connected to the wiring layer, so that the chip circuit of the sensing chip can be electrically connected to the external circuit or device, through the wiring layer at the fifth surface 350 of the substrate 200 and the connecting piece 360 to transmit electric signals.

Afterwards, a sensing chip is coupled to a surface of the substrate 300. Hereinafter processes of coupling the sensing chip to the surface of the substrate 300 are illustrated.

Reference is made to FIG. 4. The sensing chip 301 is fixed at a surface of the substrate 300. The sensing chip 301 includes a first surface 310 and a second surface 320 opposite to the first surface 310. The sensing chip 301 includes a sensing region 311 at the first surface 310, and the second surface 320 of the sensing chip 301 faces the substrate 300.

In the embodiment, the sensing chip 301 is fixed to the first surface 350 of the substrate 300 by adhering a first adhesive layer 302 to the second surface 320 of the sensing chip 301 and then adhering the first adhesive layer 302 to the fifth surface 350 of the substrate 300. Subsequently, through a wiring process, the sensing chip 301 can be coupled with the substrate 300, namely, electrically connecting the sensing chip 301 and the wiring layer at the surface of the substrate 300.

In another embodiment, a first adhesive layer may be formed on the fifth surface 350 of the substrate 300, and the sensing chip 301 can be adhered to the surface of the first adhesive layer, so that the sensing chip 301 is fixed to the surface of substrate 300.

In the embodiment, the sensing chip 301 is a fingerprint recognition chip. In the sensing region 311 of the sensing chip 301, a capacitance or inductance structure for acquiring user's fingerprint information is formed, so that the sensing region 311 can detect and receive the user's fingerprint information. In the embodiment, the sensing chip 301 further includes a peripheral region 312 at the first surface 310 which surrounds the sensing region 311. The chip circuit is formed at the peripheral region 312 at the first surface 310 of the sensing chip 301. The chip circuit is electrically connected to the capacitance structure or the inductance structure in the sensing region 311 to process electrical signals outputted by the capacitance structure and the inductance structure.

In the embodiment, at least one capacitance plate is formed in the sensing region 311. When the user's finger is placed at a surface of a cover plate formed in a following step, the capacitance plate, the cover plate and the user's finger forms a capacitance structure. The sensing region 311 can acquire a difference of the capacitance value between a ridge of the surface of the user's finger and the capacitance plate from the capacitance value between a valley of the surface of the user's finger and the capacitance plate. The difference between the capacitance values is processed by the chip circuit and then is output. Thus, user's fingerprint data is acquired.

The first surface 310 of the sensing chip 301 further includes first pads 313 at the surface of the peripheral region 312 of the sensing chip. The chip circuit is connected to the first pads 313. Subsequently, through a wiring process, the first pads 313 can be electrically connected to the wiring layer at the surface of the substrate 300.

In another embodiment, the sensing chip 301 is an image sensing chip. In the sensing region 311 of the sensing chip 301, a sensor for external image information is formed. A cover plate to be formed in the following step is located on the sensing region 311 to protect an optical region in the sensing region 311.

Reference is made to FIG. 5. The cover plate 303 is formed on the sensing region 311 of the sensing chip 301. The cover plate 303 includes a third surface 330 contacting the sensing region 311, and a fourth region 340 opposite to the third region 330.

The cover plate 303 may protect the sensing region 311. When the user's finger is placed at a surface of the cover plate 303 on the sensing region 311, the sensing region 311 can acquire the user's fingerprint information, and friction of the user's finger can not damage the sensing region 311.

In the embodiment, materials of the cover plate 330 are sapphire, ceramic substrate or glass substrate. The cover plate 303 is fixed to the first surface 310 of the sensing chip 301 through a second adhesive layer, and surfaces of the second adhesive layer has stickiness. In an embodiment, the second adhesive layer is adhered to the first surface 310 of the sensing chip 301, and then the cover plate 303 is adhered to the surface of the second adhesive layer. In another embodiment, the second adhesive layer is adhered to the surface of the cover plate 303, and then the second adhesive layer is adhered to the first surface 310 of the sensing chip 301.

In an embodiment, the cover plate is a glass substrate. The dielectric constant of the glass substrate is 6˜10 and the thickness of the glass substrate is larger than or equal to 100 μm. Due to the large dielectric constant of the cover plate 303, the cover plate 303 has strong electrical isolation ability, so the cover plate 303 has strong protection ability for the sensing region 311.

In another embodiment, the cover plate 303 is a ceramic substrate. T dielectric constant of the ceramic substrate is 20˜100, and the thickness of the ceramic substrate is 100˜200 μm. The dielectric constant of the cover plate 303 is larger than or equal to 20. Due to a larger dielectric constant of the ceramic substrate than the glass substrate, the cover plate 303 made of the ceramic substrate has stronger electrical isolation ability, so the cover plate 303 made of the ceramic substrate has stronger protection ability for the sensing region 311. And the thickness of the cover plate 303 made of the ceramic substrate can be smaller than the cover plate 303 made of the glass substrate, therefore, the size and thickness of the formed packaging structure can be reduced.

Moreover, since the cover plate 303 has a smaller thickness, when the user's finger is placed at the surface of the cover plate 303, the distance between the finger and the sensing region 311 is reduced. Therefore, it is easier for the sensing region 311 to detect the fingerprint of the user's finger, thereby reducing requirement for high sensitivity of the sensing chip 301.

The color of the second adhesive layer includes black or white. In another embodiment, a colorful pattern layer may be formed on a surface of the second adhesive layer, and the cover layer is formed on a surface of the colorful pattern layer. The color of the colorful pattern layer includes black or white. In other embodiments, the colorful pattern layer may also be other colors.

Reference is made to FIG. 6, where the sensing chip 301 is coupled with the substrate 300.

Before forming the plastic packaging layer, conductive wires 304 are formed. The ends of the conductive wires 304 are connected to the first pads 313 and the second pads 351, respectively.

Coupling the sensing chip 301 with the substrate 300 refers to electrically connecting the sensing chip 301 and the substrate 300. In the embodiment, the sensing chip 301 is coupled with the substrate 300 through the wiring process.

In the embodiment, before forming the plastic packaging layer in a following step, the conductive wires 304 are formed through the wiring process. The ends of the conductive wires 304 are connected to the first pads 313 and the second pads 351, so that the sensing chip 301 and the substrate 300 are electrically connected to each other. The conductive wires 304 can electrically connect the chip circuit to the wiring layer at the surface of the substrate 300 which is electrically connected to the connecting piece 306, so that electrical signals can be transmitted between the chip circuit and the sensing region 311 at the surface of the sensing chip 301 and the external circuit or device. Materials of the conductive wires 304 are metal. The metal is copper, tungsten, aluminum, gold, or silver. Employing the wiring process simplifies the electrical connection between the sensing chip 301 and the substrate 300, and has a low cost.

The wiring process includes: providing the conductive wires 304; and connecting the ends of the conductive wires 304 to the first pads 313 and the second pads 314 respectively. The materials of the conductive wires 304 are metal. The metal is copper, tungsten, aluminum, gold, or silver.

Because the conductive wires 304 are connected between the first pads 313 and the second pads 314, the conductive wires 307 are curved. Each conductive wire 304 has a point with a maximum distance to the surface of the substrate 300. The point of the conductive wire 304 with the maximum distance to the surface of the substrate 300 is a vertex, and the vertex is higher than the first surface 310 of the sensing chip 301 and lower that the surface of the cover plate 303. The conductive wires 304 need to be wrapped by the plastic packaging layer in the following step to electrically isolate the conductive wires from the sensing chip 301 and from the external environment, therefore, the vertex further needs to be lower than the surface of the plastic packaging layer formed in the following step, so that the plastic packaging layer formed in the following step can completely wrap the conductive wires 304, electrically isolating the conductive wires 304 from the sensing chip 301, and preventing the conductive wires 304 from being exposed.

Reference is made to FIG. 7. The plastic packaging layer 305 is formed on the surface of the substrate 300. The plastic packaging layer 305 surrounds the sensing chip 301, and covers a part of the sidewall of the cover plate 303. The surface of the plastic packaging layer 305 is higher than the third surface 330 of the cover plate 303 and lower than the fourth surface 340 of the cover plate 303.

The plastic packaging layer 305 may fix and protect the sensing chip 301, the cover plate 303 and the conductive wires 304, and electrically isolate the conductive wires 304 from the sensing chip 301, isolate the conductive wires 304 from the external environment, and isolate the sensing chip 301 from the external environment.

In the embodiment, the vertexes of the conductive wires 304 are higher than the first surface of the sensing chip 301, and the surface of the plastic packaging layer 305 is higher than the vertexes of the conductive wires 304, so that the plastic packaging layer 305 can totally wrap the conductive wires 304 to electrically isolate the conductive wires 304 from the external environment.

Materials of the plastic packaging layer 305 are polymer materials. The polymer materials have good flexibility, malleability, and coverage ability. The polymer materials are epoxy resin, polyethylene, polypropylene, polyolefin, polyamide, or polyurethane. The plastic packaging layer 305 may also be made of other proper plastic packaging materials.

The surface of the plastic packaging layer 305 is higher than the third surface 330 of the cover plate 303, namely, higher than the first surface 310 of the sensing chip 301, so that the plastic packaging layer 305 covers a part of the first surface 310 of the sensing chip 301 and a part of the sidewall of the cover plate 303. The plastic packaging layer 305 can increase the binding force between the cover plate 303 and the sensing chip 301 to prevent problems such as delamination and peeling off between the cover plate 303 and the sensing chip 301, increasing sensing sensitivity of the sensing chip 301.

The surface of the plastic packaging layer 305 is lower than the fourth surface 340 of the cover plate 303, namely, the plastic packaging layer 305 exposes the covering plate 303, thereby preventing the plastic packaging layer from hampering sensing ability of the sensing region 311, beneficial for increasing recognition performances of the sensing chip 301.

In an embodiment, the sensing chip 301 is a fingerprint recognition chip, and the plastic packaging layer 305 exposes the cover plate 303, preventing the packaging layer 305 from increasing the distance between the user's finger and the sensing region 311, thereby increasing recognition ability of the sensing chip 301.

In another embodiment, the sensing chip is an image sensing chip, and the plastic packaging layer 305 exposes the cover plate 303, thereby preventing the plastic packaging layer 305 from weakening light transmittance of the covering plate 303, and increasing sensing quality of the sensing region 311.

In the embodiment, formation technique of the plastic packaging layer 305 is fluid plastic packaging technique. In the fluid plastic packaging technique, plastic packaging materials for plastic packaging is provided to the surface of the substrate 300 and the sensing chip 301 in a liquid state or a flow state. When the thickness of the plastic packaging materials is higher than the vertexes of the conductive wires 304 and lower than the surface of the cover plate 303, the plastic packaging materials are cured to form the plastic packaging layer 305. The thickness of the formed plastic packaging layer 305 can be strictly controlled by using the fluid plastic packaging technique, ensuring that the plastic packaging layer 305 completely wraps the conductive wires 304 and the surface of the plastic packaging layer 305 is lower than the surface of the cover plate 303. The fluid plastic packaging technique of the plastic packaging layer 305 includes potting technique.

In an embodiment, the formation technique of the plastic packaging layer 305 is the potting technique, including: potting the plastic packaging materials with low viscosity at the surface of the substrate 300 and the sensing chip 301, through a liquid distributor, and when the thickness of the plastic packaging materials reaches a predetermined thickness, heating and curing the plastic packaging materials to form the plastic packaging layer 305.

In the embodiment, the plastic packaging layer 305 has the predetermined thickness. The predetermined thickness is a designed thickness which the plastic packaging layer 305 is required to reach. The predetermined thickness is required to satisfy that the plastic packaging layer 305 totally covers the substrate 300, the sensing chip 301, and the conductive wires 304, and the plastic packaging layer 305 exposes the fourth surface 340 of the cover plate 303.

Because the plastic packaging layer 305 is formed through the fluid plastic packaging technique, the thickness of the plastic packaging layer 305 can be controlled precisely, so that a range of an actual thickness of the formed plastic packaging layer 305 is from 90% of the predetermined thickness to 110% of the predetermined thickness.

In an embodiment, further included is forming a protection ring on the surface of the substrate 300. The protection ring surrounds the sensing chip 301, the plastic packaging layer 305, and the cover plate 303. Materials of the protection ring are metal. The protection ring is grounded through the substrate 300, and is fixed to the fifth surface 350 of the substrate 300.

The protection ring is located around the sensing chip 301, the cover plate 303 and the plastic packaging layer 305, and a part of the protection ring further extends above the plastic packaging layer 305 and exposes the surface of the cover plate 303 on the sensing region 311. In another embodiment, the protection ring is only located around the sensing chip 301 and the plastic packaging layer 305, and completely exposes the surface of the cover plate 303.

The materials of the protection ring are metal. The metal is copper, tungsten, aluminum, silver, or gold. The protection ring is configured for electrostatic protection for the sensing chip 301. Because the protection ring is metal, the protection ring is conductive. When the user's finger touches the cover plate 303, electrostatic charges are generated and first transmitted to the substrate 300 via the protection ring, thereby preventing the cover plate 303 from breakdown due to exaggerated electrostatic voltage, so as to protect the sensing chip 301, increase sensitivity of the fingerprint detection, and eliminate signal noise outputted by the sensing chip 301, so that the signal outputted by the sensing chip is more accurate.

In another embodiment, further included is forming a shell surrounding the plastic packaging layer 305, the sensing chip 301, the cover plate 303 and the protection ring. The shell exposes the cover plate 303 on the sensing region 301. The shell may be a shell of a device or a terminal required to set the sensing chip, or a shell of the packing structure of the sensing chip.

In another embodiment, further included is forming a shell surrounding the plastic packaging layer 305, the sensing chip 301, and the cover layer 303. The shell exposes the cover layer 305 on the sensing region 311.

In summary, in the embodiment, the cover plate is formed on the sensing region of the sensing chip, and the plastic packaging layer surrounding the sensing chip is formed on the surface of the substrate. The plastic packaging layer covers a part of the sidewall of the cover plate. The cover plate can directly contact the user's finger to protect the sensing chip. Moreover, compared with the traditional glass substrate, the cover plate can be made of materials with a smaller thickness to reduce the distance from the first surface of the sensing chip to the surface of the cover plate, facilitating the sensing chip to detect the user's fingerprint. Correspondingly, the packaging structure reduces requirement for sensitivity of the sensing chip, so that the packaging structure of the fingerprint recognition chip has a wider application. The cover plate includes the third surface contacting the sensing region and the fourth surface opposite to the third surface. The surface of the plastic packaging layer is higher than the third surface of the cover plate and lower than the fourth surface of the cover plate. Therefore, the plastic packaging layer can fix the cover plate to the first surface of the sensing chip, so that the cover plate and the sensing chip are bound together more tightly, preventing the cover plate from being delaminated or peeled off from the sensing chip, and increasing reliability of the packaging structure. And the plastic packaging layer exposes the surface of the cover plate, therefore, the plastic packaging layer does not hamper sensing performances of the sensing region of the sensing chip, and the sensing region of the sensing chip has higher sensing recognition ability.

Correspondingly, a chip packaging structure formed by the above method is provided according to an embodiment of the present disclosure, as shown in FIG. 7, including:

a substrate 300;

a sensing chip 301 coupled to a surface the substrate 300, where the sensing chip 301 includes a first surface 310 and a second surface 320 opposite to the first surface 310, and the sensing chip 301 includes a sensing region 311 at the first surface 310, and the second surface 320 of the sensing chip 301 faces the substrate 300;

a cover plate 303 on the sensing region 311 of the sensing chip 301, where the cover plate 303 includes a third surface 330 contacting the sensing region 311, and a fourth surface 340 opposite to the third surface 330; and

a plastic packaging layer 305 on the surface of the substrate 300, where the plastic packaging layer 305 surrounds the sensing chip 301 and covers a part of the sidewall of the cover plate 303, and a surface of the plastic packaging layer 305 is higher than the third surface 330 of the cover plate 303 and lower than the fourth surface 340 of the cover plate 303.

Hereinafter the above structure is illustrated in detail.

Materials of the plastic packaging layer 305 are polymer materials. The plastic packaging layer 305 has a predetermined thickness, and a range of an actual thickness of the plastic packaging layer is from 90% of the predetermined thickness to 110% of the predetermined thickness.

The sensing chip 301 is a fingerprint recognition chip or an image sensing chip. In the embodiment, the chip packaging structure further includes: the sensing chip 301 further includes a peripheral region 312 at the first surface 310 which surrounds the sensing region 311; the peripheral region 312 and the sensing region 311 of the sensing chip 301 includes a chip circuit; first pads 313 at the surface of the peripheral region 312 of the sensing chip 301; and the chip circuit is connected to the pads 313.

The substrate 300 includes a fifth surface 350. The sensing chip 310 is coupled to the fifth surface 350 of the substrate 300, and the fifth surface 350 of the substrate 330 includes second pads 351.

The chip packaging structure further includes conductive wires 304. The ends of the conductive wires 304 are connected to the first pads 313 and the second pads 351 respectively, so as to couple the sensing chip 301 with the substrate 300. Each conductive wire 304 has a point, with a maximum distance to the surface of the substrate 300. The point of the conductive wires 304 with the maximum distance to the surface of the substrate 300 is a vertex, and the vertex is higher than the first surface 310 of the sensing chip 301 and lower than the fourth surface 340 of the cover plate 303.

The chip packaging structure further includes a first adhesive layer 302 on the surface of the substrate 300 or the second surface 320 of the sensing chip 301. The sensing chip 301 is fixed to the first surface 310 of the substrate 300 through the first adhesive layer 302. In addition, in an embodiment, the first surface 310 of the sensing chip 301 and the cover plate 303 may further fixed to each other through a second adhesive layer.

Compared with conventional technology, the technical solutions of the present disclosure have following merits.

In the formation method according to the present disclosure, the cover plate is formed on the surface of the sensing region of the sensing chip, and the plastic packaging layer surrounding the sensing chip is formed on the surface of the substrate. The plastic packaging layer covers a part of the sidewall of the cover plate. The cover plate can directly contact the user's finger to protect the sensing chip. Moreover, compared with the traditional glass substrate, the cover plate can be made of materials with a smaller thickness to reduce the distance from the first surface of the sensing chip to the surface of the cover plate, facilitating the sensing chip to detect the user's fingerprint. Correspondingly, the packaging structure reduces requirement for sensitivity of the sensing chip, so that the packaging structure of the fingerprint recognition chip has a wider application. The cover plate includes the third surface contacting the sensing region and the fourth surface opposite to the third surface. The surface of the plastic packaging layer is higher than the third surface of the cover plate and lower than the fourth surface of the cover plate. Therefore, the plastic packaging layer can fix the cover plate to the first surface of the sensing chip, so that the cover plate and the sensing chip are bound together more tightly, preventing the cover plate from being delaminated or peeled off from the sensing chip, and increasing reliability of the packaging structure. And the plastic packaging layer exposes the surface of the cover plate, therefore, the plastic packaging layer does not hamper sensing performances of the sensing region of the sensing chip, and the sensing region of the sensing chip has higher sensing recognition ability.

Further, the formation technique of the plastic packaging layer is fluid plastic packaging technique. Flowing plastic packaging materials are formed at the surface of the substrate and cover the exposed surfaces of the substrate and the sensing chip and a part of the surface of the cover plate. Then the flowing plastic packaging materials are cured to form the plastic packaging layer. The surface of the formed plastic packaging layer is the liquid level of the flowing plastic packaging materials, and hence it is easy to control the surface of the plastic packaging layer through the technique, so that the surface of the formed plastic packaging layer is higher than the third surface of the cover plate and lower than the fourth surface of the cover plate. Moreover, when using the flowing plastic packaging technique, there is no need of a mold for injection molding. Thus in formation of the plastic packaging layer, pressures on the sensing chip, the substrate and the conductive wires is relatively small, which can reduce damages on the sensing chip, the substrate and the conductive wires, increasing reliability of the formed packaging structure.

Further, the sensing chip is a fingerprint recognition chip or an image sensing chip. When the sensing chip is the image sensing chip, because the surface of the plastic packaging layer is lower than the fourth surface of the cover plate, the cover plate is exposed. Thus light can directly enter the cover plate and reach the sensing region of the sensing chip. The plastic packaging layer does not weaken the light entering the sensing region, so the image sensing chip has high sensing quality and high sensitivity.

In the structure according to the present disclosure, the cover plate is provided on the surface of the sensing region of the sensing chip, the plastic packaging layer surrounding the sensing chip is provided on the surface of the substrate, and the plastic packaging layer covers a part of the sidewall of the cover plate. The cover plate can directly contact the user's finger to protect the sensing chip. Moreover, compared with the traditional glass substrate, the cover plate can be made of materials with a smaller thickness to reduce the distance from the first surface of the sensing chip to the surface of the cover plate, facilitating the sensing chip to detect the user's fingerprint. Correspondingly, the packaging structure reduces requirement for sensitivity of the sensing chip, so that the packaging structure of the fingerprint recognition chip has a wider application. The cover plate includes the third surface contacting the sensing region and the fourth surface opposite to the third surface. The surface of the plastic packaging layer is higher than the third surface of the cover plate and lower than the fourth surface of the cover plate. Therefore, the plastic packaging layer can fix the cover plate to the first surface of the sensing chip, so that the cover plate and the sensing chip are bound together more tightly, preventing the cover plate from being delaminated or peeled off from the sensing chip, and increasing reliability of the packaging structure. And the plastic packaging layer exposes the surface of the cover plate, therefore, the plastic packaging layer does not hamper sensing performances of the sensing region of the sensing chip, and the sensing region of the sensing chip has high sensing recognition ability.

In summary, in the embodiment, the cover plate is provided on the sensing region of the sensing chip, and the plastic packaging layer surrounding the sensing chip is provided on the surface of the substrate, and the plastic packaging layer covers a part of the sidewall of the cover plate. The cover plate can directly contact the user's finger to protect the sensing chip. Moreover, compared with the traditional glass substrate, the cover plate can be made of materials with a smaller thickness to reduce the distance from the first surface of the sensing chip to the surface of the cover plate, facilitating the sensing chip to detect the user's fingerprint. Correspondingly, the packaging structure reduces requirement for sensitivity of the sensing chip, so that the packaging structure of the fingerprint recognition chip has a wider application. The cover plate includes the third surface contacting the sensing region and the fourth surface opposite to the third surface. The surface of the plastic packaging layer is higher than the third surface of the cover plate and lower than the fourth surface of the cover plate. Therefore, the plastic packaging layer can fix the cover plate to the first surface of the sensing chip, so that the cover plate and the sensing chip are bound together more tightly, preventing the cover plate from being delaminated or peeled off from the sensing chip, and increasing reliability of the packaging structure. And the plastic packaging layer exposes the surface of the cover plate, therefore, the plastic packaging layer does not hamper sensing performances of the sensing region of the sensing chip, and the sensing region of the sensing chip has high sensing recognition ability.

Although the present disclosure is disclosed hereinabove, the present disclosure is not limited to the above. Any skilled in the art may make various modifications and alternations without deviating from the spirit and the scope of the present disclosure. Therefore, the protection scope of the present disclosure should be confirmed by the scope limited by the claims.

1. A chip packaging structure, comprising:
a substrate;
a sensing chip coupled with the substrate, wherein the sensing chip comprises a first surface and a second surface opposite to the first surface, the sensing chip further comprises a sensing region at the first surface, and the second surface of the sensing chip faces the substrate;
a cover plate on the sensing region of the sensing chip, wherein the cover plate comprises a third surface contacting the sensing region and a fourth surface opposite to the third surface; and
a plastic packaging layer on the substrate, wherein the plastic packaging layer surrounds the sensing chip and covers a part of a sidewall of the cover plate, and a surface of the plastic packaging layer is higher than the third surface of the cover plate and lower than the fourth surface of the cover plate.

2. The chip packaging structure according to claim 1, wherein the plastic packaging layer comprises polymer materials.

3. The chip packaging structure according to claim 1, wherein the sensing chip further comprises a peripheral region at the first surface which surrounds the sensing region, the peripheral region and the sensing region of the sensing chip comprises a chip circuit, the peripheral region of the sensing chip comprises a first pad, and the chip circuit is electrically connected to the first pad.

4. The chip packaging structure according to claim 3, wherein the substrate comprises a fifth surface, the sensing chip is coupled to the fifth surface of the substrate, and the fifth surface of the substrate comprises a second pad.

5. The chip packaging structure according to claim 4, further comprising: a conductive wire, wherein two ends of the conductive wire are electrically connected to the first pad and the second pad respectively.

6. The chip packaging structure according to claim 5, wherein the conductive wire has a point with a maximum distance to the fifth surface of the substrate, the point of the conductive wire with the maximum distance to the fifth surface of the substrate is a vertex, and the surface of the plastic packaging layer is higher than the vertex and lower than the fourth surface of the cover plate.

7. The chip packaging structure according to claim 1, further comprising: a first adhesive layer on the substrate or the second surface of the sensing chip, wherein the sensing chip is fixed to the substrate through the first adhesive layer.

8. The chip packaging structure according to claim 1, further comprising: a second adhesive layer on the first surface of the sensing chip and the cover plate on the surface of the second adhesive layer.

9. A chip packaging method, comprising:
providing a substrate;
coupling a sensing chip with the substrate, wherein the sensing chip comprises a first surface and a second surface opposite to the first surface, the sensing chip further comprises a sensing region at the first surface, and the second surface of the sensing chip faces the substrate;
forming a cover plate on the sensing region of the sensing chip, wherein the cover plate comprises a third surface contacting the sensing region and a fourth surface opposite to the third surface; and
forming a plastic packaging layer on the substrate, wherein the plastic packaging layer surrounds the sensing chip and covers a part of a sidewall of the cover plate, and a surface of the plastic packaging layer is higher than the third surface of the cover plate and lower than the fourth surface of the cover plate.

10. The chip packaging method according to claim 9, wherein the plastic packaging layer is formed by a fluid plastic package technique.

11. The chip packaging method according to claim 10, wherein the plastic packaging layer is formed by a potting technique.

12. The chip packaging method according to claim 9, the plastic packaging layer comprises polymer materials.

13. The chip packaging method according to claim 9, wherein the sensing chip further comprises a peripheral region at the first surface which surrounds the sensing region, the peripheral region and the sensing region of the sensing chip comprises a chip circuit, the peripheral region of the sensing chip comprises a first pad, and the chip circuit is electrically connected to the first pad.

14. The chip packaging method according to claim 13, wherein the substrate comprises a fifth surface, the sensing chip is coupled to the fifth surface of the substrate, and the fifth surface of the substrate comprises a second pad.

15. The chip packaging method according to claim 14, further comprising forming a conductive wire before forming the plastic packaging layer, wherein two ends of the conductive wire are electrically connected to the first pad and the second pad respectively.

16. The chip packaging method according to claim 15, wherein the conductive wire has a point with a maximum distance to the fifth surface of the substrate, the point of the conductive wire with the maximum distance to the fifth surface of the substrate is a vertex, and the surface of the plastic packaging layer is higher than the vertex and lower than the fourth surface of the cover plate.

17. The chip packaging method according to claim 9, further comprising: forming a first adhesive layer on the substrate or the second surface of the sensing chip, before coupling the sensing chip with the substrate; and fixing the sensing chip to the substrate through the first adhesive layer.

18. The chip packaging method according to claim 9, further comprising: forming a second adhesive layer on the first surface of the sensing chip; and forming the cover plate on the second adhesive layer.
